(19) United States
(12) Patent Application Publication
(10) Pub. No.: US 2024/0213260 A1
(43) Pub. Date: Jun. 27, 2024

(54) ARRAY SUBSTRATE, MANUFACTURING METHOD THEREOF, AND DISPLAY PANEL

(71) Applicant: GUANGZHOU CHINA STAR OPTOELECTRONICS SEMICONDUCTOR DISPLAY TECHNOLOGY CO., LTD., Guangzhou (CN)

(72) Inventors: Shan LI, Guangzhou (CN); Juncheng XIAO, Guangzhou (CN); Bin ZHAO, Guangzhou (CN); Mingjiue YU, Guangzhou (CN); Lanlan LI, Guangzhou (CN); Qiang WANG, Guangzhou (CN)

(73) Assignee: GUANGZHOU CHINA STAR OPTOELECTRONICS SEMICONDUCTOR DISPLAY TECHNOLOGY CO., LTD., Guangzhou (CN)

(21) Appl. No.: 18/192,649

(22) Filed: Mar. 30, 2023

(30) Foreign Application Priority Data
Dec. 21, 2022 (CN) 202211652814.4

(51) Int. Cl. H01L 27/12

(52) U.S. Cl. CPC H01L 27/1237; H01L 27/127

(57) ABSTRACT

An array substrate, a manufacturing method thereof, and a display panel are provided by the present application. The array substrate includes an active layer, a gate electrode and an interlayer insulation layer. A content of hydrogen in the interlayer insulation layer is greater than or equal to a content of hydrogen in the active layer, and the hydrogen in the interlayer insulation layer can be transferred to the active layer. A sheet resistance value of the active layer is less than 1000 ohm/square. Because the hydrogen in the interlayer insulation layer can directly diffuse and transfer to the active layer, the hydrogen content in the active layer can be increased to achieve the purpose of conductivity, thus eliminating the process of ion doping in the active layer, simplifying a preparation process of the array substrate, and improving comprehensive performance of the array substrate.

### BACKGROUND OF INVENTION

### Field of Invention

The present application relates to a technical field of design and manufacture of display panel, in particular to an array substrate and a manufacturing method thereof, and a display panel.

### Description of Prior Art

With the continuous development of preparation technology of a display panel, people have put forward high requirements for various performances of the display panel and a device.

It is necessary to form an array substrate and a plurality of thin film transistors in the array substrate when forming the display panel in the prior art, so as to ensure normal use of the display panel. Among them, each of the thin film transistors generally includes functional film layers such as a source electrode, a drain electrode, a gate electrode and an active layer. Multiple etching processes are generally adopted when forming the above-mentioned functional film layers, such as sequentially depositing and etching to form an active layer patterned structure, a gate electrode patterned structure. Etching to form via holes and opening structures. Etching to form a source/drain metal layer. The active layer will be further conductorized after the gate electrode patterned structure is processed. Usually, ions are used to bombard the active layer, so that the ions are formed in the active layer, thereby carrier migration efficiency in the active layer is effectively improved, contact resistance is improved, and performance of the thin film transistor is improved. However, in the process of ion bombardment doping of the active layer, the bombardment efficiency will be affected, and then reduce the performance of the active layer after processing due to the influence of material properties of the active layer and other factors such as the bombardment process or film thickness, which is not conducive to further improvement of comprehensive performance of the thin film transistor.

In summary, the thin film transistor prepared in the prior art is carrying out ion doping to the active layer of the thin-film transistor, the doping effect is unsatisfactory, and the doping process is complicated, which is not conducive to the further improvement of the comprehensive performance of the thin film transistor.

### SUMMARY OF INVENTION

Embodiments of the present application are directed to an array substrate, a manufacturing method thereof, and a display panel, which can effectively improve the problems of a manufacturing process of a thin film transistor in an existing display panel is complex and a comprehensive performance of the thin film transistor is poor.

To solve the above technical problems, an array substrate is provided in the present application, the array substrate includes:
an active layer;
a gate electrode insulation disposed on the active layer;
an interlayer insulating layer covering the gate electrode and the active layer; and
a source/drain metal layer, disposed on the interlayer insulating layer and connected to the active layer;
wherein a content of hydrogen in the interlayer insulating layer is greater than or equal to a content of hydrogen in the active layer, and sheet resistance value of the active layer is less than 1000 ohm/square at a position corresponding to the source/drain metal layer.

According to an embodiment of the present application, the active layer includes a first region, a second region and a third region between the first region and the second region;
wherein the interlayer insulating layer corresponding to the third region is disposed on the gate electrode, and the source/drain metal layer is disposed on the interlayer insulating layer corresponding to the first region and the second region.

According to an embodiment of the present application, contents of hydrogen in the first region and the second region in the active layer are greater than or equal to a content of hydrogen in the third region of the active layer.

According to an embodiment of the present application, each of the first region and the second region of the active layer includes a first concentration region and a second concentration region;
wherein the second concentration region is disposed on a side close to the gate electrode, the first concentration region is disposed on a side away from the gate electrode, and a sheet resistance value of the active layer in the first concentration region is ranged between 100 ohm/square and 500 ohm/square, and a sheet resistance value of the active layer in the second concentration region is ranged between 500 ohm/square and 1000 ohm/square.

According to an embodiment of the present application, a content of the hydrogen on a side of the interlayer insulating layer close to the active layer is not less than a content of the hydrogen on a side of the interlayer insulating layer away from the active layer in the first concentration region and the second concentration region in a thickness direction of the interlayer insulating layer.

According to an embodiment of the present application, a content of the hydrogen on a side of the active layer close to the interlayer insulating layer is not less than a content of the hydrogen on a side of the active layer away from the interlayer insulating layer in the first concentration region and the second concentration region in a thickness direction of the active layer.

According to an embodiment of the present application, the interlayer insulating layer includes a first interlayer insulating layer and a second interlayer insulating layer disposed on the first interlayer insulating layer; wherein a content of hydrogen in the first interlayer insulating layer is not less than a content of hydrogen in the second interlayer insulating layer.

According to an embodiment of the present application, materials of the interlayer insulating layer includes any one of SiNₓ, CHO organic molecular material and SiOCH polymer material.

According to the embodiment of the present application, a display panel is also provided, includes the array substrate provided in the present application.

According to the third aspect of the embodiment of the present application, a manufacturing method of array substrate is also provided, including following steps:
providing a substrate, and depositing an active layer on the substrate;
depositing a gate insulating layer on the active layer, and depositing a gate electrode on the gate insulating layer;
patterning the gate insulating layer and the gate electrode, and depositing an interlayer insulating layer on the gate electrode and the active layer; wherein a content of hydrogen in the interlayer insulating layer is greater than a content of hydrogen in the active layer;
heat-treating the interlayer insulating layer, the hydrogen in the interlayer insulating layer is transferred to a region of the active layer not in contact with the gate insulating layer, so that the region of the gate insulating layer not in contact with the active layer is conductorized;
preparing a passivation layer on the interlayer insulating layer.

Advantageous effects: an array substrate, a manufacturing method thereof, and a display panel are provided by embodiments of the present application. The array substrate includes an active layer, a gate electrode and an interlayer insulating layer, and a part of the interlayer insulating layer is disposed on the active layer and covers the gate electrode. In the embodiment of the present application, a material of the interlayer insulating layer is a hydrogen-rich material, and the hydrogen in the interlayer insulating layer can be transferred to the active layer. Meanwhile, the sheet resistance value of the active layer is less than 1000 ohm/square. The hydrogen in the interlayer insulating layer can be diffused and transferred into the active layer, thereby increasing the content of hydrogen in the active layer to achieve the conductor performance, thus effectively eliminating an ion doping process of the active layer, a preparation process of the array substrate is simplified, uniformity of the performance of the film layer is ensured, and the comprehensive performance of the array substrate is improved.

### BRIEF DESCRIPTION OF DRAWINGS

In order to more clearly illustrate the embodiments or the technical solutions of the existing art, the drawings illustrating the embodiments, or the existing art will be briefly described below. The drawings in the following description merely illustrate some embodiments of the present application. Other drawings may also be obtained by those skilled in the art according to these figures without paying creative work.

FIG. 1 is a schematic diagram of a layer structure of the array substrate provided by an embodiment of the present application.

FIG. 2 is a schematic diagram of a partial film layer structure of the array substrate provided by an embodiment of the present application.

FIG. 3 is a schematic diagram of a partial film layer structure of another array substrate provided by an embodiment of the present application.

FIG. 4 is a schematic diagram of a manufacturing method of the array substrate provided by an embodiment of the present application.

FIG. 5 is a schematic diagram of a film layer structure corresponding to an array substrate preparation process provided by an embodiment of the present application.

### DETAILED DESCRIPTION OF PREFERRED EMBODIMENTS

Below in conjunction with the accompanying drawings in the embodiments of the present application, the disclosure below provides different implementations or examples to realize different structures of the present application. To simplify the present application, the components and arrangements of specific examples are described below. In addition, various specific process and material examples are provided herein, and those of ordinary skill in the art may recognize the application of other processes. All other embodiments obtained by those skilled in the art without creative efforts fall within the protection scope of the present application.

In the description of the present application, that an orientation or position relationship indicated by terms “center”, “longitudinal”, “transverse”, “length”, “width”, “thickness”, “upper”, “lower”, “front””, “back”, “left”, “right”, “vertical”, “horizontal”, “top”, “bottom”, “inside”, “outside”, “clockwise”, “counterclockwise” are based on the orientation or positional relationship shown in the drawings, it is only for the convenience of describing the present application and simplifying the description, but not to indicate or imply that the device or element referred to must have a specific orientation, be constructed and operate in a specific orientation, and therefore cannot be understood as a limitation of the present application. In addition, terms “first” and “second” are only used for describing purposes, and cannot be understood as indicating or implying relative importance or implying the number of technical features indicated.

With the continuous development of preparation technology of an array substrate and a display panel, people have put forward higher requirements on performance and display effect of the display panel.

A plurality of thin film transistors are formed in the array substrate in a process of forming the array substrate. The active layer and other functional film layers in the thin film transistor have an important influence on performance of the thin film transistor. In an existing manufacturing process, the active layer needs to be subjected to a conductive process, and the conductive process is usually carried out by ion doping, and the purpose is achieved by bombarding the active layer with plasma gas. However, the above-mentioned ion doping process is relatively complicated, and there are many control conditions, and in the ion doping process, there are still problems such as unsatisfactory doping effect and high production cost.

The array substrate and a manufacturing method thereof are provided by the embodiment of the present application, which can effectively simplify a process flow of the array substrate and improve comprehensive performance of the array substrate.

Refer to FIG. 1 illustrating a schematic diagram of a layer structure of the array substrate according to an embodiment of the present application.

The array substrate includes a substrate 101, a light shielding layer 108 and a buffer layer 102. The light shielding layer 108 is disposed on the substrate 101. The buffer layer 102 is disposed on the substrate 101 and completely covers the light shielding layer 108. The substrate 101 may be a glass substrate or a substrate of other materials to support film layers on the substrate 101. The buffer layer 102 can be a flexible film layer, such as a flexible polyimide film layer. The buffer layer 102 can be multiple buffer layers or a single flexible polyimide film layer.

Furthermore, a thin film transistor is correspondingly arranged in the array substrate in the embodiment of the present application. The thin film transistor includes an active layer 105, a source/drain electrode metal layer, a gate electrode 109, an interlayer insulating layer 103 and a gate insulating layer 110. The source/drain electrode metal layer is described by taking a source electrode 107 and a drain electrode 106 as examples.

The thin film transistor is disposed on the buffer layer 102. The active layer 105 is disposed on the buffer layer 102. The gate insulating layer 110 is disposed on the active layer 105. The gate electrode 109 is disposed on the gate insulating layer 110. The interlayer insulating layer 103 is disposed on the buffer layer 102, and covers the gate electrode 109 and a part of the active layer 105.

In the embodiment of the present application, the active layer 105 is disposed above the light shielding layer 108. A length of the light shielding layer 108 is greater than a length of the active layer 105, which ensures light shielding effect of the light shielding layer 108. Meanwhile, via holes 441 are also defined on both sides of the interlayer insulating layer 103. Via holes 441 penetrate through the interlayer insulating layer 103 to expose the active layer 105. Furthermore, the source electrode 107 is in contact with the active layer 105 through one of via hole 441, and the drain 106 is also in contact with the active layer 105 through another one of via hole 441. A passivation layer 104 is disposed on the interlayer insulating layer 103, and the passivation layer 104 covers the source electrode 107 and the drain electrode 106, so as to form the film structure of an entire thin film transistor.

In the embodiment of the present application, the thin film transistor is a top-gate thin film transistor. The gate insulating layer 110 is directly disposed on the active layer 105. The gate electrode 109 is directly disposed on the gate insulating layer 110. A length of the gate electrode 109 and a length of the gate insulating layer 110 are smaller than the length of the active layer 105. Therefore, the gate insulating layer 110 can only cover the part of the active layer 105, and edge regions on both sides of the active layer 105 cannot be covered by the gate insulating layer 110 and the gate electrode 109.

Specifically, the surface of the film layer at the edge regions on both sides of the active layer 105 is directly in contact with the interlayer insulating layer 103, and is covered by the interlayer insulating layer 103.

In the embodiment of the present application, a material of the interlayer insulating layer 103 is a hydrogen-rich material, and a content of hydrogen in the material of the interlayer insulating layer 103 is greater than or equal to a content of hydrogen in the active layer. Specifically, in the hydrogen-rich interlayer insulating layer 103, since the interlayer insulating layer 103 is in direct contact with the active layer 105, the hydrogen in the interlayer insulating layer 103 can directly diffused to and migrated to the active layer 105, so that in a region where the interlayer insulating layer 103 and the active layer 105 are in contact, the active layer 105 receives more hydrogen, and the hydrogen is enriched in a corresponding region, and the active layer corresponding to the area is conductorized, thereby forming a semiconductor layer of the thin film transistor.

In the embodiment of the present application, the hydrogen in the interlayer insulating layer 103 is directly transferred to the active layer 105, so that the active layer achieves a purpose of ion doping. Treatment process of conducting the active layer through ion bombardment in an existing process is omitted, thereby effectively simplifying the production process flow and ensuring the performance of the active layer.

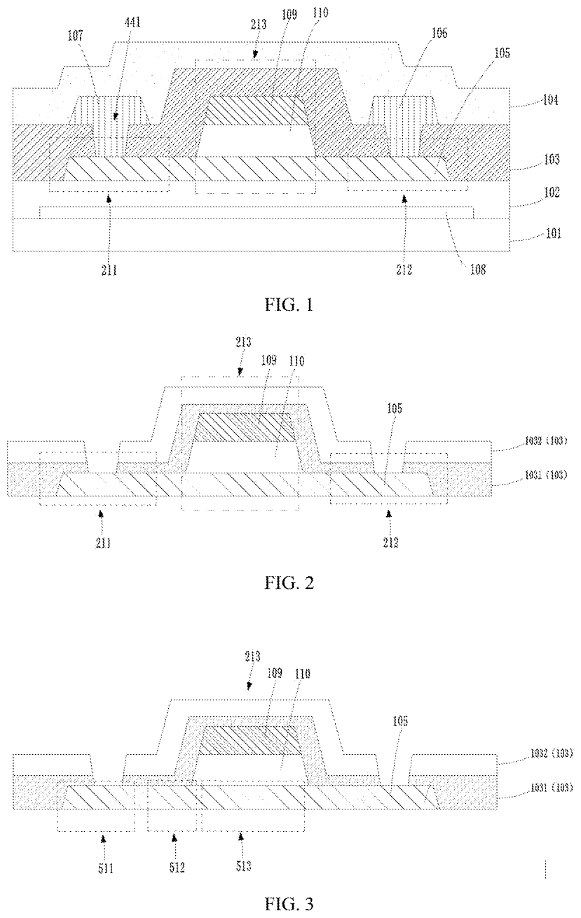

Specifically, as shown in FIG. 2, FIG. 2 is a schematic diagram of a partial film layer structure of the array substrate provided by an embodiment of the present application. With reference to the array substrate in FIG. 1, the active layer includes a first region 211, a second region 212 and a third region 213 in the embodiment of the present application.

The first region 211 and the second region 212 are correspondingly disposed on both sides of the active layer. The third region 213 is disposed between the first region 211 and the second region 212. Specifically, the first region 211 is adjacent to the third region 213. The second region 212 is adjacent to the third region 213. The interlayer insulating layer 103 is directly in contact with the active layer 105 in the first region 211 and the second region 212, and the interlayer insulating layer 103 is directly in contact with the gate electrode 109 in the third region 213.

In the embodiment of the present application, since the interlayer insulating layer 103 is the hydrogen-rich material, such as the hydrogen-rich material is hydrogen atoms or hydrogen ions, the above-mentioned hydrogen atoms or hydrogen ions can diffuse and transfer into the active layer 105, so that the corresponding active layer 105 in the first region 211 and the second region 212 can achieve particle doping and conduction.

In the embodiment of the present application, contents of hydrogen in the active layer 105 corresponding to the first region 211 and the second region 212 are both not less than a content of hydrogen in the active layer 105 corresponding to the third region 213. Preferably, the content of hydrogen in the active layer 105 in the first region 211 and the content of hydrogen in the active layer 105 in the second region 212 are same, and greater than the content in hydrogen in the third region 213.

Preferably, in the interlayer insulating layer 103, contents of hydrogen in the interlayer insulating layer 103 corresponding to the first region 211 and the second region 212 are not less than a content of hydrogen in the interlayer insulating layer 103 corresponding to the third region. Preferably, the contents of hydrogen in the interlayer insulating layer 103 in the first region 211 and the second region 212 are the same, and greater than the content of hydrogen in the third region 213.

In the embodiment of the present application, since the hydrogen in the active layer 105 is transferred through the interlayer insulating layer 103. Therefore, the interlayer insulating layer 103 can be set as a multilayer film layer. In the following embodiments, the interlayer insulating layer 103 includes a first interlayer insulating layer 1031 and a second interlayer insulating layer 1032 for illustration. According to different products, the above-mentioned interlayer insulating layer may be provided with other number of film layers, which will not be repeated here.

Preferably, the first interlayer insulating layer 1031 is disposed on the active layer 105 and covers the part of the active layer 105, and the second interlayer insulating layer 1032 is disposed on the first interlayer insulating layer 1031.

Furthermore, since the first interlayer insulating layer 1031 is directly in contact with the active layer 105, the first interlayer insulating layer 1031 is directly transferred into the active layer 105 in the first region 211 and the second region 212 when the hydrogen transfer is performed, thereby saving the ion bombardment doping process of the active layer 105 and improving the performance of the array substrate.

In the embodiment of the present application, film materials of the two different interlayer insulating layers can be set as hydrogen-rich materials when the above-mentioned first interlayer insulating layer 1031 and the second interlayer insulating layer 1032 are set. Specifically, in the embodiment of the present application, the hydrogen-rich material may include any one of SiNₓ, CHO organic molecular material, and SiOCH polymer material. The interlayer insulating layers are formed by using the above materials to effectively increase the hydrogen content in the interlayer insulating layer.

Specifically, two interlayer insulating layers may be made of a same material or different materials. For example, both the first interlayer insulating layer 1031 and the second interlayer insulating layer 1032 may be CHO organic molecular materials.

Furthermore, the first interlayer insulating layer 1031 and the second interlayer insulating layer 1032 can also be made of different materials. Specifically, the material of the first interlayer insulating layer 1031 is SiNₓ, the material of the second interlayer insulating layer 1032 is SiOₓ, or, the material of the first interlayer insulating layer 1031 is CHO organic molecular material or SiOCH polymer material, and the material of the second interlayer insulating layer 1032 is SiNₓ. Thus, the transfer effect of hydrogen atoms in the interlayer insulating layer is ensured.

Specifically, a content of hydrogen in the first interlayer insulating layer 1031 may not be less than a content of hydrogen in the second interlayer insulating layer 1032. In this way, the first interlayer insulating layer 1031 can transfer more hydrogen atoms into the active layer 105 to improve the performance of the active layer.

A thickness of the first interlayer insulating layer 1031 can be greater than a thickness of the second interlayer insulating layer 1032, so that more hydrogen atoms can be gathered in the first interlayer insulating layer 1031, thereby ensuring the transfer effect of the interlayer insulating layer. Specifically, the thickness of the first interlayer insulating layer 1031 and the thickness of the second interlayer insulating layer 1032 range from 3000 Å to 5000 Å. For example, the thickness of the first interlayer insulating layer 1031 is 3000 Å, 4000 Å, etc. The specific thickness can be set according to different product requirements, and will not be repeated here.

As shown in FIG. 3, FIG. 3 is a schematic diagram of a partial film layer structure of another array substrate provided by an embodiment of the present application. In combination with the film layer structure in FIG. 1 and FIG. 2, the active layer 105 further includes a first concentration region 511, a second concentration region 512 and a third concentration region 513 in the embodiment of the present application. The first concentration region 511 and the second concentration region 512 are correspondingly arranged in the first region 211 and the second region 212. The third concentration region 513 may be correspondingly arranged in the third region 213. In the embodiment of the present application, only the first region 211 is taken as an example for illustration.

The active layer corresponding to the first region 211 and the second region 212 is equivalent to doped regions of the thin film transistor, and the third region 213 is equivalent to thin film a channel region of the thin film transistor after the transfer of hydrogen atoms in the interlayer insulating layer 103 is stable. The source electrode 107 and the drain electrode 106 are correspondingly connected to the doped regions, so as to realize the transmission of control signals and the transfer of carriers in the active layer.

In the embodiment of the present application, the content of the hydrogen in the first concentration region 511 is greater than the content of the hydrogen in the second concentration region 512 when the above-mentioned different concentration zones are set. Moreover, the contents of hydrogen in the first concentration region 511 and the second concentration region 512 are both greater than the content of hydrogen in the third concentration region 513, so as to ensure migration effect of carriers in the active layer and the comprehensive performance of the display panel.

In the embodiment of the present application, the source electrode 107 is correspondingly disposed in the first concentration region 511. A length of the first concentration region 511 may be greater than a length of the second concentration region 512.

Furthermore, in the embodiment of the present application, a sheet resistance value of the active layer 105 may be less than 1000 ohm/square after the transfer of hydrogen in the interlayer insulating layer 103 is stable. Therefore, the performance of the active layer and the normal operation of the display panel are guaranteed.

Specifically, the sheet resistance value of the active layer 105 ranges from 100 ohm/square to 500 ohm/square in the first concentration region 511. Preferably, the sheet resistance value of the active layer in the first concentration region 511 is Any one of 100 ohm/square, 200 ohm/square, 300 ohm/square or 400 ohm/square, so that there is a higher hydrogen in the first concentration region 511.

The square resistance value of the active layer 105 ranges from 500 ohm/square to 1000 ohm/square in the second concentration region 512. Preferably, the square resistance value of the active layer corresponding to the second concentration region 512 is any one of 500 ohm/square, 600 ohm/square, 700 ohm/square or 800 ohm/square, so that a gradient difference is formed between the first concentration region 511 and the second concentration region 512, thereby ensuring working effect and performance of the display panel.

In the embodiment of the present application, the hydrogen in different regions of the active layer is directly transferred from the interlayer insulating layer. Therefore, amount of the hydrogen contained in the active layer 105 at different film positions can be set to be different.

Specifically, a content of hydrogen on a side of the active layer 105 close to the interlayer insulating layer 103 is not less than a content of hydrogen on a side of the active layer 105 away from the interlayer insulating layer 103 in a thickness direction of the active layer 105. Specifically, for example, the content of hydrogen in a half film layer corresponding to an upper half of the active layer 105 is greater than or equal to the content of hydrogen in a lower half of the active layer at a half the thickness of the active layer 105.

Similarly, there is a certain relationship between the transfer effect and a distance since the hydrogen in the interlayer insulating layer 103 is transferred. Therefore, the content of hydrogen in the active layer 105 on a side close to the interlayer insulating layer 103 is not less than the content of hydrogen in the active layer 105 on a side away from the interlayer insulating layer 103 in the second concentration region 512. Therefore, the carrier transfer efficiency in the active layer 105 is effectively guaranteed, and the comprehensive performance of the display panel is improved.

Furthermore, in combination with the structure of the array substrate in FIG. 1 to FIG. 3, a thickness of the gate insulating layer 109, the source electrode 107 and the drain electrode 106 are a same when setting each film layer. The thicknesses of the source electrode 107 and the drain electrode 106 do not include a thickness of the source electrode 107 and the drain electrode 106 disposed in the via holes 441. In this way, the gate insulating layer 110, the source electrode 107 and the drain electrode 106 are at the same height after etching, thereby the structure of each film layer is guaranteed, a total thickness of the array substrate is reduced, and a light and thin display panel is realized.

That is, in the embodiment of the present application, a height between a bottom surface of the gate insulating layer 110 and a surface of the active layer 105 is as the same as a height between a bottom surface of the source/drain metal layer and a surface of the active layer 105. The source/drain metal layer includes the source electrode 107 and the drain electrode 106.

Specifically, in the embodiment of the present application, a thickness of the gate insulating layer 110 ranges from 2000 Å to 5000 Å. Optionally, the thickness of the gate insulating layer 110 can be 2000 Å, 3000 Å or 4000 Å. Meanwhile, a thickness of the gate electrode 109 ranges from 3000 Å to 5000 Å. Optionally, the thickness of the gate electrode 109 is 3000 Å, 4000 Å or 4500 Å.

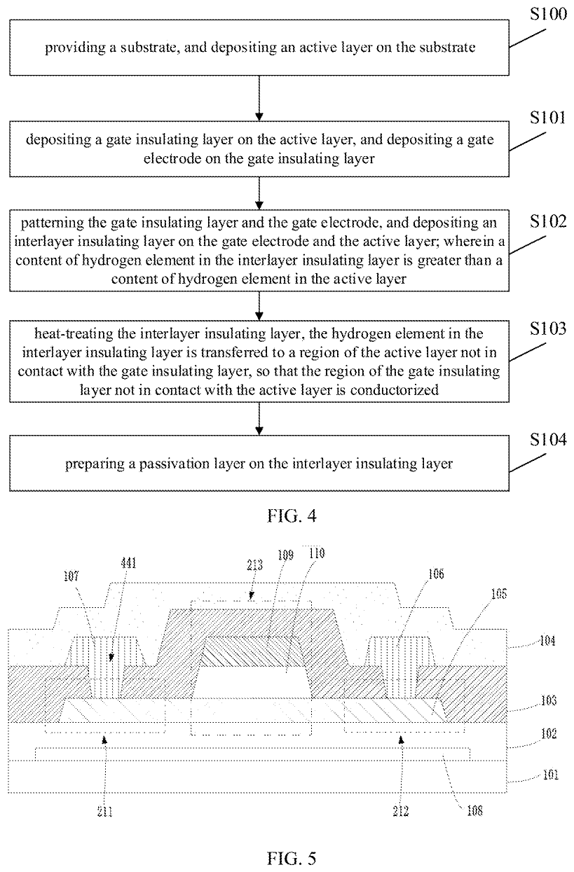

Furthermore, as shown in FIG. 4 illustrating a schematic diagram of a manufacturing method of the array substrate provided by an embodiment of the present application. the manufacturing method of the array substrate includes following steps:
S100: Providing a substrate, and depositing an active layer on the substrate.
S101: Depositing a gate insulating layer on the active layer, and depositing a gate electrode on the gate insulating layer.
S102: Patterning the gate insulating layer and the gate electrode, and depositing an interlayer insulating layer on the gate electrode and the active layer; wherein a content of hydrogen in the interlayer insulating layer is greater than a content of hydrogen in the active layer.
S103: Heat-treating the interlayer insulating layer, the hydrogen in the interlayer insulating layer is transferred to a region of the active layer not in contact with the gate insulating layer, so that the region of the gate insulating layer not in contact with the active layer is conductorized.
S104: Preparing a passivation layer on the interlayer insulating layer.

As shown in FIG. 5, FIG. 5 is a schematic diagram of a film layer structure corresponding to an array substrate preparation process provided by an embodiment of the present application. Depositing a light shielding layer 108 on the substrate 101 when forming the array substrate in the embodiment of the present application. A material of the light shielding layer 108 can be any one or alloy of Cu/Ti/Mo.

Depositing a buffer layer 102 on the light shielding layer 108 after the light shielding layer 108 is deposited. The buffer layer 102 is used to insulate the light shielding layer 108 from the active layer 105. commonly used materials of the buffer layer 102 can be selected form materials such as polyimide or SiOₓ/SiNₓ. A thickness of the buffer layer 102 ranges from 3000 Å to 5000 Å. Specifically, the thickness of the buffer layer 102 in the array substrate is 4000 Å, 4500 Å, etc.

Depositing and Patterning an active layer 105 after the buffer layer 102 is prepared. Depositing a gate insulating layer 110 on the active layer 105 after the active layer 105 is processed, and a gate electrode 109 is deposited on the gate insulating layer 110. Then, patterning the gate insulating layer 110 and gate electrode 109.

Further, depositing an interlayer insulating layer 103 on the gate electrode 109 and the active layer 105. The interlayer insulating layer 103 is a hydrogen-rich material. Specifically, materials of the interlayer insulating layer 103 can be selected as any one of SiNₓ, CHO organic molecular material and SiOCH polymer material. The specific parameters of its film layer can be set according to the structure provided in the embodiment of the present application when the above-mentioned interlayer insulating layer 103 is provided.

Specifically, heat-treating the interlayer insulating layer after depositing the interlayer insulating layer. If the above-mentioned film layer is transferred to a certain temperature, such as heating at 50° C. to 120° C., the hydrogen in the interlayer insulating layer 103 will diffuse and transfer to the active layer 105 under the effect of temperature, so that hydrogen atoms are enriched in a corresponding region of the active layer 105, and the hydrogen atoms make the corresponding positions on both sides of the active layer 105 conductive.

In the embodiment of the present application, since the interlayer insulating layer 103 is the hydrogen-rich material, the hydrogen can be automatically transferred to the active layer 105, so as to improve transfer efficiency of the hydrogen transferred to the active layer 105, thereby improving the preparation efficiency of the film layer.

Simultaneously, a certain temperature will be applied in different processes, and a higher temperature will promote the diffusion efficiency of hydrogen in the interlayer insulating layer 103 when forming the above-mentioned array substrate. Therefore, the hydrogen in the interlayer insulating layer 103 can be fully transferred to the active layer after the array substrate is formed, and the performance of the active layer 105 can be ensured.

Furthermore, via holes 441 are defined by etching at corresponding positions after the interlayer insulating layer 103 is formed. Depositing a passivation layer 104 on the interlayer insulating layer 103, and then etching the passivation layer 104. In the embodiment of the present application, the passivation layer 104 may be processed by a dry etching process. Materials of the passivation layer can be selected as SiON/SiNₓ or other inorganic insulating materials. Meanwhile, a thickness of the passivation layer 104 ranges from 3000 Å to 5000 Å. Therefore, sealing performance of the passivation layer 104 is ensured, and the comprehensive performance of the display panel is improved.

A sheet resistance value of the active layer 105 is less than 1000 ohm/square after the preparation is completed. Thereby, the performance of the active layer 105 is ensured. In the embodiment of the present application, the hydrogen in the interlayer insulating layer 103 is transferred to the active layer 105 by directly changing the material of the interlayer insulating layer 103 which is the hydrogen-rich material, thereby the conductorization process of the active layer 105 is realized, the existing doping process is avoided.

Furthermore, a display panel and a display device are provided by an embodiment of the present application. Specifically, the display panel includes the array substrate provided in the embodiment of the present application, and the interlayer insulating layer and the active layer and other film layer structures in the array substrate are set using the structure in the present application, thereby the film layer process of the display panel is effectively simplified, and its comprehensive performance is improved.

In the embodiment of the present application, the array substrate and a corresponding display panel and display device can be any product or component with display function or touch control function such as mobile phone, computer, electronic paper, display, etc., and its specific type is not make specific restrictions.

To sum up, above, the array substrate and the manufacturing method thereof provided by the embodiment of the present application have been introduced in detail. In this paper, specific examples are used to explain the principle and implementation of the present application. The above examples are only used to help understand the technical solution and core idea of the present application. Although the present application is disclosed as above with preferred embodiments, the above preferred embodiments are not intended to limit the present application. Ordinary technicians in the art can make various changes and refinishes without departing from the spirit and scope of the present application. Therefore, the scope of protection of the present application is based on the scope defined by the claims.

What is claimed is:

1. An array substrate, comprising:
an active layer;
a gate electrode insulation disposed on the active layer; and
an interlayer insulating layer covering the gate electrode and the active layer; and
a source/drain metal layer, disposed on the interlayer insulating layer and connected to the active layer;
wherein a content of hydrogen in the interlayer insulating layer is greater than or equal to a content of hydrogen in the active layer, and a sheet resistance value of the active layer is less than 1000 ohm/square at a position corresponding to the source/drain metal layer.

2. The array substrate according to claim 1, wherein the active layer comprises a first region, a second region, and a third region between the first region and the second region;
wherein the interlayer insulating layer corresponding to the third region is disposed on the gate electrode, and the source/drain metal layer is disposed on the interlayer insulating layer corresponding to the first region and the second region.

3. The array substrate according to claim 2, wherein contents of hydrogen in the first region and the second region in the active layer are greater than or equal to a content of hydrogen in the third region of the active layer.

4. The array substrate according to claim 2, wherein each of the first region and the second region of the active layer comprises a first concentration region and a second concentration region;
wherein the second concentration region is disposed on a side close to the gate electrode, the first concentration region is disposed on a side away from the gate electrode, and a sheet resistance value of the active layer in the first concentration region is ranged between 100 ohm/square and 500 ohm/square, and a sheet resistance value of the active layer in the second concentration region is ranged between 500 ohm/square and 1000 ohm/square.

5. The array substrate according to claim 4, wherein a content of the hydrogen on a side of the interlayer insulating layer close to the active layer is not less than a content of the hydrogen on a side of the interlayer insulating layer away from the active layer in the first concentration region and the second concentration region in a thickness direction of the interlayer insulating layer.

6. The array substrate according to claim 4, wherein a content of the hydrogen on a side of the active layer close to the interlayer insulating layer is not less than a content of the hydrogen on a side of the active layer away from the interlayer insulating layer in the first concentration region and the second concentration region in a thickness direction of the active layer.

7. The array substrate according to claim 1, wherein the interlayer insulating layer comprises a first interlayer insulating layer and a second interlayer insulating layer disposed on the first interlayer insulating layer; wherein a content of hydrogen in the first interlayer insulating layer is not less than a content of hydrogen in the second interlayer insulating layer.

8. The array substrate according to claim 1, wherein materials of the interlayer insulating layer comprise any one of SiNₓ, CHO organic molecular material and SiOCH polymer material.

9. A display panel, comprising an array substrate, the array substrate comprising:
an active layer;
a gate electrode insulation disposed on the active layer;
an interlayer insulating layer covering the gate electrode and the active layer; and
a source/drain metal layer, disposed on the interlayer insulating layer and connected to the active layer;
wherein a content of hydrogen in the interlayer insulating layer is greater than or equal to a content of hydrogen in the active layer, and a sheet resistance value of the active layer is less than 1000 ohm/square at a position corresponding to the source/drain metal layer.

10. The display panel according to claim 9, wherein the active layer comprises a first region, a second region, and a third region between the first region and the second region;
wherein the interlayer insulating layer corresponding to the third region is disposed on the gate electrode, and the source/drain metal layer is disposed on the interlayer insulating layer corresponding to the first region and the second region.

11. The display panel according to claim 10, wherein contents of hydrogen in the first region and the second region in the active layer are greater than or equal to a content of hydrogen in the third region of the active layer.

12. The display panel according to claim 10, wherein each of the first region and the second region of the active layer comprises a first concentration region and a second concentration region;
wherein the second concentration region is disposed on a side close to the gate electrode, the first concentration region is disposed on a side away from the gate electrode, and a sheet resistance value of the active layer in the first concentration region is ranged between 100 ohm/square and 500 ohm/square, and a sheet resistance value of the active layer in the second concentration region is ranged between 500 ohm/square and 1000 ohm/square.

13. The display panel according to claim 12, wherein a content of the hydrogen on a side of the interlayer insulating layer close to the active layer is not less than a content of the hydrogen on a side of the interlayer insulating layer away from the active layer in the first concentration region and the second concentration region in a thickness direction of the interlayer insulating layer.

14. The display panel according to claim 12, wherein a content of the hydrogen on a side of the active layer close to the interlayer insulating layer is not less than a content of the hydrogen on a side of the active layer away from the interlayer insulating layer in the first concentration region and the second concentration region in a thickness direction of the active layer.

15. The display panel according to claim 9, wherein the interlayer insulating layer comprises a first interlayer insulating layer and a second interlayer insulating layer disposed on the first interlayer insulating layer; wherein a content of hydrogen in the first interlayer insulating layer is not less than a content of hydrogen in the second interlayer insulating layer.

16. The display panel according to claim 9, wherein materials of the interlayer insulating layer comprise any one of SiNₓ, CHO organic molecular material and SiOCH polymer material.

17. A manufacturing method of an array substrate, comprising following steps:
providing a substrate, and depositing an active layer on the substrate;
depositing a gate insulating layer on the active layer, and depositing a gate electrode on the gate insulating layer;
patterning the gate insulating layer and the gate electrode, and depositing an interlayer insulating layer on the gate electrode and the active layer; wherein a content of hydrogen in the interlayer insulating layer is greater than a content of hydrogen in the active layer;
heat-treating the interlayer insulating layer, the hydrogen in the interlayer insulating layer is transferred to a region of the active layer not in contact with the gate insulating layer, so that the region of the gate insulating layer not in contact with the active layer is conductorized;
preparing a passivation layer on the interlayer insulating layer.
